(19) United States
(12) Patent Application Publication
(10) Pub. No.: US 2024/0280375 A1
(43) Pub. Date: Aug. 22, 2024

(54) METHOD AND APPARATUS FOR MAPPING INDOOR

(71) Applicant: Samsung Electronics Co., Ltd., Suwon-si (KR)

(72) Inventors: Juan LIU, Nanjing (CN); Hyuncheol Park, Suwon-si (KR); Dowan Kim, Suwon-si (KR); Jie Chen, Nanjing (CN); Longhai Wu, Nanjing (CN)

(73) Assignee: SAMSUNG ELECTRONICS CO., LTD., Suwon-si (KR)

(21) Appl. No.: 18/397,299

(22) Filed: Dec. 27, 2023

Related U.S. Application Data
(63) Continuation of application No. PCT/KR23/19359, filed on Nov. 28, 2023.

(30) Foreign Application Priority Data
Feb. 22, 2023 (CN) 202310153191.4

(51) Int. Cl. G01C 21/00; G06T 11/60

(52) U.S. Cl. CPC G01C 21/383; G06T 11/60; G06T 2210/04

(57) ABSTRACT

A method for mapping indoor includes: generating, based on a standard house plan of a target house, vectorized house structure data for the target house using a deep neural network; acquiring a first radar map by scanning a travelable space of a first region with a radar, the first region containing at least one room of the target house; and performing image matching-fusion processing based on the first radar map and the house structure data to obtain a house display plan of the target house.

### CROSS-REFERENCE TO RELATED APPLICATION(S)

This application is a bypass continuation of International Application No. PCT/KR2023/019359, filed on Nov. 28, 2023, which is based on and claims priority to CN patent application Ser. No. 20/231,0153191.4, filed on Feb. 22, 2023, in the China National Intellectual Property Administration, the disclosures of which are incorporated by reference herein in their entireties.

### BACKGROUND

### 1. Field

The disclosed embodiments relate to computer application technology, and more particularly to a method and apparatus for indoor mapping.

### 2. Description of Related Art

With the increasing application of sweeping robots in the family, the real-time radar map of the house structure may be obtained using the radars they carry. At present, there are many mapping methods for sweeping robots on the market, mainly based on visual mapping and radar mapping, among which radar mapping is mainly used.

House-type display plans acquired by the conventional radar mapping methods have some problems, such as low accuracy and incompleteness.

For example, due to the complexity of the layout of various furniture and appliances in the actual home environment, the moving range of the conventional sweeping robot is limited by the obstruction of various objects on the ground, failing to traverse all regions of the room, thus resulting in a radar map with a lot of noise and incompleteness.

### SUMMARY

In view of the above, a primary object of the disclosed embodiments are to provide a method and apparatus for mapping indoor, which can improve the accuracy and integrity of the generation of a house-type display plan.

In order to achieve the above object, the technical solutions provided in embodiments may include:

A method for mapping indoor may include: generating, based on a standard house plan of a target house, vectorized house structure data for the target house using a deep neural network; acquiring a first radar map by scanning a travelable space of a first region with a radar, the first region containing at least one room of the target house; and performing image matching-fusion processing based on the first radar map and the house structure data to obtain a house display plan of the target house.

The acquiring the first radar map by scanning the travelable space of the first region with the radar may include: scanning the travelable space of the first region by using the radar to obtain an original radar map; and filtering a noise region in the original radar map to obtain the first radar map.

The performing the image matching-fusion processing may include: constructing a plurality of standard house sub-plans of the target house based on the house structure data, the plurality of standard house sub-plans containing at least one room of the target house; selecting a first standard house sub-plan that best matches with the first radar map from the plurality of standard house sub-plans; determining a matching adjustment angle of the first radar map corresponding to the first standard sub-plan, the matching adjustment angle being an angle at which the first radar map needs to rotate and/or flip in order to be consistent with a direction of the first standard house sub-plan; determining, for each first room in the first radar map, a room corresponding to the first room in the first standard house sub-plan; performing optimization iterative fitting on a center position, length, and width of the first room by taking a size of the room corresponding to the first room as a target to obtain a size-matching parameter of the first room, the size-matching parameter including a center position, length, and width of the first room, and room identification information; and performing adjustment on the first radar map based on the matching adjustment angle and the size-matching parameter of the first room to obtain the house display plan of the target house.

The selecting the first standard house sub-plan that best matches with the first radar map from the plurality of standard house sub-plans, and the determining the matching adjustment angle of the first radar map corresponding to the first standard sub-plan may include: performing room segmentation on the first radar map, a segmented room of the first radar map with a maximum area being a main region; determining first similarities between the main region and each of the plurality of standard house sub-plans by (i) taking the matching adjustment angle as a similarity parameter, (ii) selecting a first similarity greater than a preset coarse similarity threshold, and (iii) taking a matching adjustment angle corresponding to the first similarity selected as a candidate matching adjustment angle corresponding to the first standard house sub-plan; adjusting the first radar map based on each candidate matching adjustment angle; calculating second similarities between an adjusted first radar map and the corresponding standard house sub-plan, the second similarities being obtained using a weighted calculation method based on a preset fine similarity parameter, the fine similarity parameter including an intersection ratio, a coverage rate, and/or an length-width ratio; taking a standard house sub-plan of the plurality of standard house sub-plans corresponding to a maximum value of the second similarities as the first standard house sub-plan that best matches with the first radar map; and taking a corresponding candidate matching adjustment angle as the corresponding matching adjustment angle of the first radar map.

The determining, for each first room in the first radar map, the corresponding room of the first room in the first standard house sub-plan may include: calculating a similarity between the first room and each room in the first standard house sub-plan with an intersection ratio as a similarity parameter; and taking a room corresponding to a maximum similarity as the corresponding room of the first room in the first standard house sub-plan.

The performing the image matching-fusion processing may further include, for each first room: determining, in a case that there is a second room, a size ratio between a standard house size of the first room and the size-matching parameter of the first room, the second room being a room of the target house excluded from the first radar map, the standard house size being size data of the corresponding room of the first room in the first standard house sub-plan; adjusting corresponding vectorized house structure data of each second room according to an average value of the size ratio to obtain a size-matching parameter of the second room; and adding a corresponding room to the house display plan based on the size-matching parameter of the second room.

Rooms within the standard house sub-plan may have connectivity.

A device for mapping indoor may include a memory; and at least one processor configured to: generate, based on a standard house plan of a target house, vectorized house structure data for the target house using a deep neural network; acquire a first radar map by scanning a travelable space of a first region with a radar, the first region containing at least one room of the target house; and perform image matching-fusion processing based on the first radar map and the house structure data to obtain a house display plan of the target house.

The at least one processor being configured to acquire the first radar map by scanning the travelable space of the first region with the radar may include being configured to: scan the travelable space of the first region by using the radar to obtain an original radar map; and filter a noise region in the original radar map to obtain the first radar map.

The at least one processor being configured to perform image matching-fusion processing may include being configured to: construct a plurality of standard house sub-plans of the target house based on the house structure data, the plurality of standard house sub-plans containing at least one room of the target house; select a first standard house sub-plan that best matches with the first radar map from the plurality of standard house-type sub-plans; determine a matching adjustment angle of the first radar map corresponding to the first standard sub-plan, the matching adjustment angle being an angle at which the first radar map needs to rotate and/or flip in order to be consistent with a direction of the first standard house sub-plan; determine, for each first room in the first radar map, a room corresponding to the first room in the first standard house sub-plan; perform optimization iterative fitting on a center position, length, and width of the first room by taking a size of the room corresponding to the first room as a target to obtain a size-matching parameter of the first room, the size-matching parameter including a center position, length, and width of the first room, and room identification information; and perform adjustment on the first radar map based on the matching adjustment angle and the size-matching parameter of the first room to obtain the house display plan of the target house.

The at least one processor being configured to select the first standard house sub-plan that best matches with the first radar map from the plurality of standard house-type sub-plans, and to determine the matching adjustment angle of the first radar map corresponding to the first standard sub-plan may include being configured to: perform room segmentation on the first radar map, a segmented room of the first radar map with a maximum area being a main region; determine first similarities between the main region and each of the plurality of standard house sub-plans by (i) taking the matching adjustment angle as a similarity parameter, (ii) selecting a first similarity greater than a preset coarse similarity threshold, and (iii) taking a matching adjustment angle corresponding to the first similarity selected as a candidate matching adjustment angle corresponding to the first standard house sub-plan; adjust the first radar map based on each candidate matching adjustment angle; calculate second similarities between an adjusted first radar maps and the corresponding standard house sub-plan, the second similarities being obtained using a weighted calculation method based on a preset fine similarity parameter, the fine similarity parameter including an intersection ratio, a coverage rate, and/or an length-width ratio; take a standard house sub-plan of the plurality of standard house sub-plans corresponding to a maximum value of the second similarities as the first standard house-type sub-plan that best matches with the first radar map; and take a corresponding candidate matching adjustment angle as the corresponding matching adjustment angle of the first radar map.

The at least one processor being configured to determine, for each first room in the first radar map, the corresponding room of the first room in the first standard house sub-plan may include being configured to: calculate a similarity between the first room and each room in the first standard house sub-plan with an intersection ratio as a similarity parameter; and take a room corresponding to a maximum similarity as the corresponding room of the first room in the first standard house sub-plan.

The at least one processor being configured to perform image matching-fusion processing further may include being configured to, for each first room: determine, in a case that there is a second room, a size ratio between a standard house size of the first room and the size-matching parameter of the first room the second room being a room of the target house excluded from the first radar map, the standard house size being size data of the corresponding room of the first room in the first standard house sub-plan; adjust corresponding vectorized house structure data of each second room according to an average value of the size ratio to obtain a size-matching parameter of the second room; and add a corresponding room to the house display plan based on the size-matching parameter of the second room.

Rooms within the standard house sub-plan may have connectivity.

A computer-readable storage medium may store therein computer-readable instructions, the computer-readable instructions being used for executing a method. The method may include: generating, based on a standard house-type plan of a target house, vectorized house-type structure data for the target house using a deep neural network; acquiring a first radar map by scanning a travelable space of a first region with a radar, the first region containing at least one room of the target house; and performing image matching-fusion processing based on the first radar map and the house-type structure data to obtain a house-type display plan of the target house.

The acquiring the first radar map by scanning the travelable space of the first region with the radar may include: scanning the travelable space of the first region by using the radar to obtain an original radar map; and filtering a noise region in the original radar map to obtain the first radar map.

The performing the image matching-fusion processing may include: constructing a plurality of standard house sub-plans of the target house based on the house structure data, the plurality of standard house sub-plans containing at least one room of the target house; selecting a first standard house sub-plan that best matches with the first radar map from the plurality of standard house sub-plans; determining a matching adjustment angle of the first radar map corresponding to the first standard sub-plan, the matching adjustment angle being an angle at which the first radar map needs to rotate and/or flip in order to be consistent with a direction of the first standard house sub-plan; determining, for each first room in the first radar map, a room corresponding to the first room in the first standard house sub-plan; performing optimization iterative fitting on a center position, length, and width of the first room by taking a size of the room corresponding to the first room as a target to obtain a size-matching parameter of the first room, the size-matching parameter including a center position, length, and width of the first room, and room identification information; and performing adjustment on the first radar map based on the matching adjustment angle and the size-matching parameter of the first room to obtain the house display plan of the target house.

The selecting the first standard house sub-plan that best matches with the first radar map from the plurality of standard house sub-plans, and the determining the matching adjustment angle of the first radar map corresponding to the first standard sub-plan may include: performing room segmentation on the first radar map, a segmented room of the first radar map with a maximum area being a main region; determining first similarities between the main region and each of the plurality of standard house sub-plans by (i) taking the matching adjustment angle as a similarity parameter, (ii) selecting a first similarity greater than a preset coarse similarity threshold, and (iii) taking a matching adjustment angle corresponding to the first similarity selected as a candidate matching adjustment angle corresponding to the first standard house sub-plan; adjusting the first radar map based on each candidate matching adjustment angle; calculating second similarities between an adjusted first radar map and the corresponding standard house sub-plan, the second similarities being obtained using a weighted calculation method based on a preset fine similarity parameter, the fine similarity parameter including an intersection ratio, a coverage rate, and/or an length-width ratio; taking a standard house sub-plan of the plurality of standard house sub-plans corresponding to a maximum value of the second similarities as the first standard house sub-plan that best matches with the first radar map; and taking a corresponding candidate matching adjustment angle as the corresponding matching adjustment angle of the first radar map.

The determining, for each first room in the first radar map, the corresponding room of the first room in the first standard house sub-plan may include: calculating a similarity between the first room and each room in the first standard house sub-plan with an intersection ratio as a similarity parameter; and taking a room corresponding to a maximum similarity as the corresponding room of the first room in the first standard house sub-plan.

The performing the image matching-fusion processing further may include, for each first room: determining, in a case that there is a second room, a size ratio between a standard house size of the first room and the size-matching parameter of the first room, the second room being a room of the target house excluded from the first radar map, the standard house size being size data of the corresponding room of the first room in the first standard house sub-plan; adjusting corresponding vectorized house structure data of each second room according to an average value of the size ratio to obtain a size-matching parameter of the second room; and adding a corresponding room to the house display plan based on the size-matching parameter of the second room.

### BRIEF DESCRIPTION OF THE DRAWINGS

FIG. 1 is a flow diagram of a method according to an embodiment;

FIG. 2 is a diagram illustrating generation of vectorized house-type structure data using a deep neural network according to an embodiment;

FIG. 3 is a diagram illustrating construction of all standard house-type sub-plans of a target house based on house-type structure data outputted from a deep neural network in an embodiment;

FIGS. 4 to 7 are implementation diagrams of an embodiment in Scenario I; and

FIG. 8 is a structural diagram of an apparatus according to an embodiment.

### DETAILED DESCRIPTION

In order to make the objects, technical solutions, and advantages of the disclosed embodiments clearer, the disclosed embodiments will be further described in detail below with reference to the drawings and implementations.

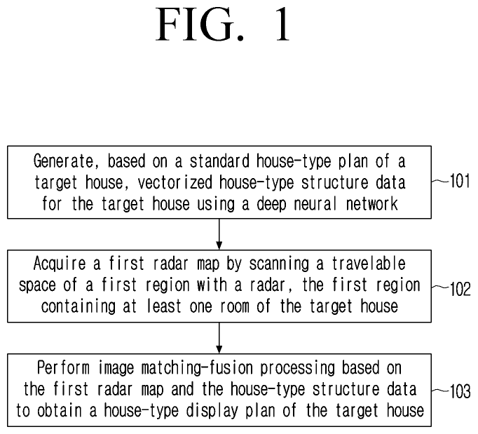

FIG. 1 is a flow diagram of a method according to an embodiment. As shown in FIG. 1, a method for mapping indoor, implemented by the embodiment, mainly includes the following steps:

Step 101: Generate, based on a standard house-type plan of a target house, vectorized house-type structure data for the target house using a deep neural network.

In the step, it is necessary to generate corresponding vectorized house-type structure data based on the standard house-type plan of the target house, to perform matching-fusion correction on radar map data based on the vectorized house-type structure data of the standard house-type plan in the subsequent steps.

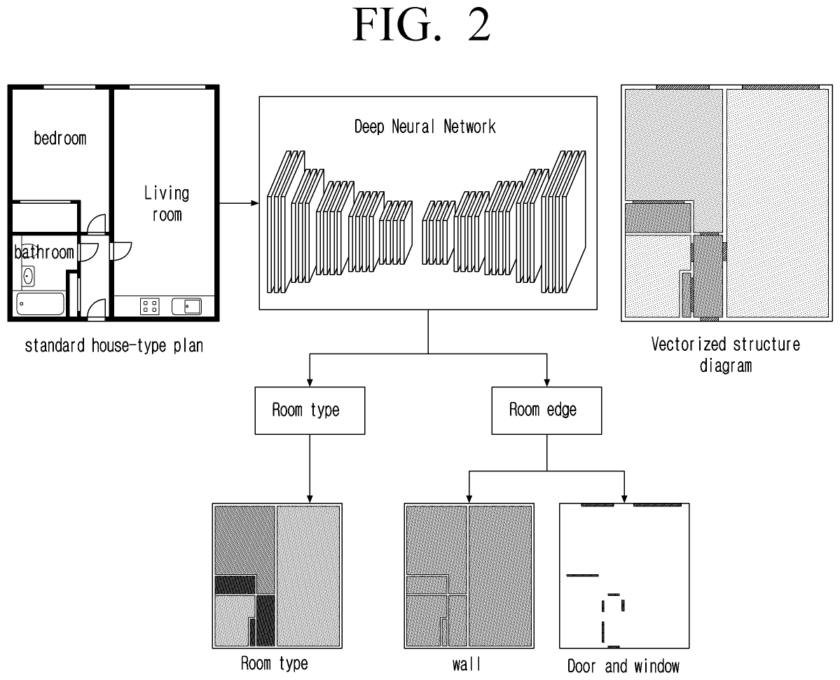

FIG. 2 provides a diagram of generation of vectorized house-type structure data in the step. As shown in FIG. 2, the standard house-type plan of the target house is input into a pre-trained deep neural network to generate a house-type structure and identify the positions of walls, doors, and windows and various rooms, to construct a vectorized structure information map, including a room category map, and a wall, door, and window position map of the target house. In this way, vectorized structure data (that is, wall structure information including door and window positions) of each room may be obtained using a standard house-type plan as input and combined with a depth learning algorithm.

In practical application, the deep neural network may be specifically obtained using existing methods, which will not be repeated herein.

Step 102: Acquire a first radar map by scanning a travelable space of a first region with a radar, the first region containing at least one room of the target house.

The step is used for acquiring a radar map of some or all the rooms of the target house. In actual implementations, a lidar map may be generated for the target house by the sweeper; and the lidar map may be specifically implemented using existing methods, such as, but not limited to, simultaneous localization and mapping (SLAM) algorithms.

Considering that the actual indoor environment may appear noise data such as corner burr due to the occlusion of various furniture or the lidar encountering the transparent glass material or highly reflective objects, thus affecting the accuracy of the house-type plan, the original radar map may be denoised in order to improve the accuracy of the radar map. Accordingly, in one implementation, the following methods may be specifically adopted: acquiring a first radar map by scanning a travelable space of a first region with a radar;

scanning the travelable space of the first region by using the radar to obtain an original radar map; and filtering a noise region in the original radar map to obtain the first radar map.

In one implementation, a region growing method may be specifically used in the above method to filter the noise region in the original radar map, but the method is not limited thereto, and other existing noise region filtering methods may also be used.

In practical application, there is no requirement on the performing order between step 101 and step 102, that is, it is not limited to performing step 101 and step 102 in the above order.

Step 103: Perform image matching-fusion processing based on the first radar map and the house-type structure data to obtain a house-type display plan of the target house.

The step is used for performing image matching-fusion processing on the radar map obtained in step 102 using the vectorized house-type structure data of the standard house-type, to obtain an accurate and complete house-type display plan.

In one implementation, the following method may be specifically used to perform the image matching-fusion processing.

Step 1031: Construct all standard house-type sub-plans of the target house based on the house-type structure data, the standard house-type sub-plans containing at least one room of the target house.

The step is used for constructing all the standard house-type sub-plans of the target house based on the generated vectorized house-type structure data, to provide the radar map data with the standard house-type data of the matching region in the subsequent steps, and further to perform fusion correction on the radar map data.

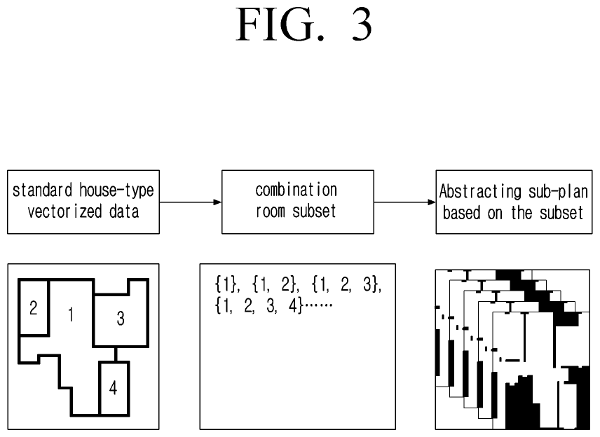

FIG. 3 is a diagram illustrating construction of all standard house-type sub-plans of a target house based on house-type structure data outputted from a deep neural network in step 101. As shown in FIG. 3, for the constructing all the standard house-type sub-plans of the target house, particularly, various rooms of the target house are arbitrarily combined to acquire room subsets in the standard house-type plan, each room subset being composed of at least one room, and then a corresponding standard house-type sub-plan is acquired based on vectorized structure data of each room subset.

The existing sweeping robot needs to traverse all regions of the room when using radar mapping to obtain indoor maps before using the acquired radar data to generate the corresponding indoor maps. Thus, the mapping efficiency of the sweeper robot is low due to the need to traverse the entire target region (that is, the entire region covered by the target map), especially when the target region is large. For this reason, in order to improve the mapping efficiency, only a part of the room may be scanned with the radar, that is, the radar map may contain only a part of the room, for example, the sweeper only sweeps out the living room and kitchen region. Accordingly, in step 1031, all the standard house-type sub-plans that may be constructed are constructed, and an arbitrary subset layout of various rooms of the standard house-type is obtained, so that in the subsequent steps, the standard house-type data of the matching region is provided for the radar map data to perform fusion correction on the radar map data.

In one implementation, considering that the regions scanned by the radar are generally connected, it is possible to construct only a standard house-type sub-plan with connectivity in order to increase processing speed and save computational overhead, that is, the rooms within the standard house-type sub-plan need to have connectivity.

Step 1032: Select a first standard house-type sub-plan matching best with the first radar map from the standard house-type sub-plans, and determine a corresponding matching adjustment angle of the first radar map, the matching adjustment angle being an angle at which the first radar map needs to rotate and/or flip in order to be consistent with a direction of the first standard house-type sub-plan.

The step is used for determining an angle at which the first radar map needs to rotate and/or flip in order to make the direction of the first radar map be consistent with that of the first standard house-type sub-plan, that is, the above matching adjustment angle.

In one implementation, step 1032 may be specifically implemented using the following steps 10321 to 10324.

Step 10321: Perform room segmentation on the first radar map, and take a segmented room with a maximum area as a main region.

Step 10322: Determine first similarities between the main region and each of the standard house-type sub-plans by taking the matching adjustment angle as a similarity parameter, select a first similarity greater than a preset coarse similarity threshold, and take a matching adjustment angle corresponding to the first similarity selected as a candidate matching adjustment angle corresponding to the first standard house-type sub-plan.

The step is used for performing coarse matching based on the main region to obtain the first several standard house-type sub-plans with a high similarity, and taking matching adjustment angles corresponding to these standard house-type sub-plans as candidate matching adjustment angles, to perform fine matching based on the candidate matching adjustment angles in subsequent step 10323 to acquire the best matching standard house-type sub-plans.

In practical application, the coarse similarity threshold may be specifically set by the skilled in the art according to matching requirements in the practical application, which will not be repeated herein.

Step 10323: Adjust the first radar map based on each candidate matching adjustment angle, and calculate second similarities between an adjusted first radar maps and the corresponding standard house-type sub-plan, the second similarities being obtained using a weighted calculation method based on a preset fine similarity parameter, and the fine similarity parameter including an intersection ratio, a coverage rate, and/or an length-width ratio.

In the step, for each candidate matching adjustment angle, the first radar map is adjusted using the candidate matching adjustment angle; then the similarity between the adjusted radar map and the standard house-type sub-plan corresponding to the candidate matching adjustment angle is calculated according to each fine similarity parameter; and finally, weighted calculation is performed based on the similarity corresponding to all the fine similarity parameters to obtain the integrated similarity (namely, the second similarity) between the adjusted radar map and the corresponding standard house-type sub-plan. In this way, a standard house-type sub-plan best matching the first radar map is selected based on the integrated similarity in subsequent step 10324.

Step 10324: Take a standard house-type sub-plan corresponding to a maximum value of the second similarities as the first standard house-type sub-plan matching best with the first radar map, and take a corresponding candidate matching adjustment angle as the corresponding matching adjustment angle of the first radar map.

Step 1033: Determine, for each first room in the first radar map, a room corresponding to the first room in the first standard house-type sub-plan, and perform optimization iterative fitting on a center position, length, and width of the first room by taking a size of the room corresponding to the first room as a target to obtain a size-matching parameter of the first room, the size-matching parameter including a center position, length, and width of a room, and room identification information.

The step is used for, for each room in the first radar map, generating a size-matching parameter of the room based on the corresponding room in the matched first standard house-type sub-plan, to optimize the size of the room in the radar map using the corresponding room in the first standard house-type sub-plan.

In one implementation, the following method may be specifically used to determine, for each first room in the first radar map, a corresponding room (namely, a matched room) of the first room in the first standard house-type sub-plan:
calculating a similarity between the first room and each room in the first standard house-type sub-plan with an intersection ratio as a similarity parameter, and taking a room corresponding to a maximum similarity as the corresponding room of the first room in the first standard house-type sub-plan.

Step 1034: Perform adjustment on the first radar map based on the matching adjustment angle and the size-matching parameter of the first room to obtain the house-type display plan of the target house.

In the step, based on the matching adjustment angles and the size-matching parameters of each room obtained in step 1032 and step 1033, corresponding direction and size adjustments are performed on the radar map, and finally a house-type display plan with accurate room semantic identification information is obtained.

Since the size-matching parameter not only includes position and size data of a room, but also includes semantic information about the room (namely, room identification information), the house-type display plan obtained in the step has semantic information about each room, thereby facilitating the use of various services based on the understanding of the spatial structure.

In a practical application scenario, the radar map may contain only map data of a part of the rooms; in this case, for other rooms in the target house which are not in the radar map, the ratio between the matching size of each room in the radar map and the corresponding standard house-type size may be used to adjust the standard house-type size of other rooms in the target house which are not in the radar map, to obtain the corresponding size-matching parameter in the house-type display plan. Accordingly, the above image matching-fusion processing method may further include the following steps:

Step x1: Determine, in a case that there is a second room, a size ratio between a standard house-type size of the first room and the size-matching parameter of the first room for each first room, the second room being a room of the target house excluded from the first radar map, and the standard house-type size being size data of the corresponding room of the first room in the first standard house-type sub-plan.

Step x2: Adjust corresponding vectorized house-type structure data of each second room according to an average value of the size ratio to obtain a size-matching parameter of the second room.

Step x3: Add a corresponding room to the house-type display plan based on the size-matching parameter of the second room.

Based on the above solution, it may be seen that the method introduces a standard house-type plan of a target house, and performs matching-fusion with radar map data using vectorized house-type structure data corresponding to the standard house-type plan, to obtain a house-type display plan of the target house. In this way, the effect of complex indoor environment on the accuracy and integrity of the radar map may be effectively solved, to obtain a complete house-type display plan matching with the actual indoor environment. Furthermore, the size-matching parameter of each room in the house-type display plan has room identification information, so that the house-type display plan has room semantic information, namely, the house-type display plan is a semantic map. Thus, with the house-type display plan obtained, it is possible to create an indoor three-dimensional (3D) map and facilitate the use of various services based on the understanding of the spatial structure of the target house, such as intelligent control of home Internet of Things (IoT) devices and intelligent indoor interaction of robots. Therefore, the technical solution may not only obtain a house-type display plan with semantic information, which is beneficial to understanding the spatial structure of the target house, but also effectively improve the accuracy and integrity of the generation of the house-type display plan. Specific applications of the embodiments are described in detail below in connection with two specific application scenarios.

Scenario I: The scanning region of the intelligent sweeper is precisely controlled by a service APP on the mobile phone, and for example, may be implemented using the following steps a1 to a4.

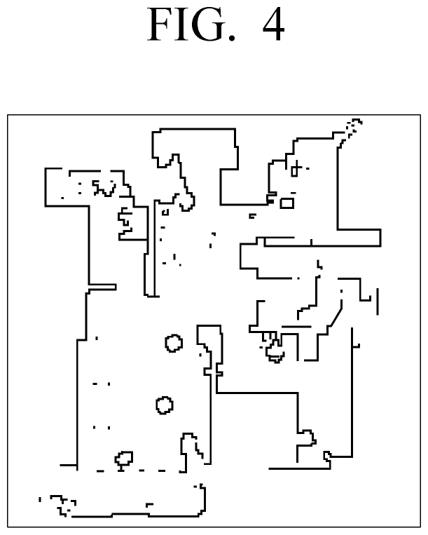

Step a1: The sweeper uses a lidar to scan a target room for indoor mapping, and the service APP on the mobile phone acquires a corresponding radar map, as shown in FIG. 4.

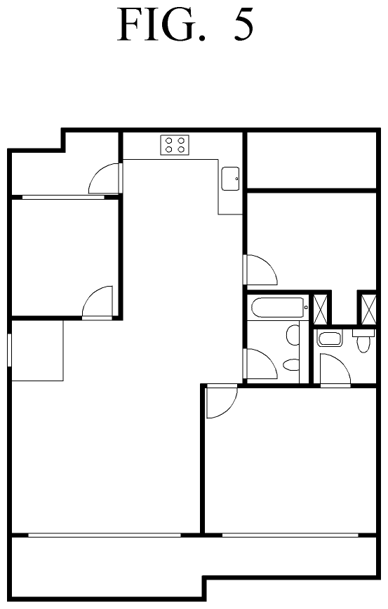

Step a2: The service APP on the mobile phone inputs a standard house-type plan of the selected target room, as shown in FIG. 5.

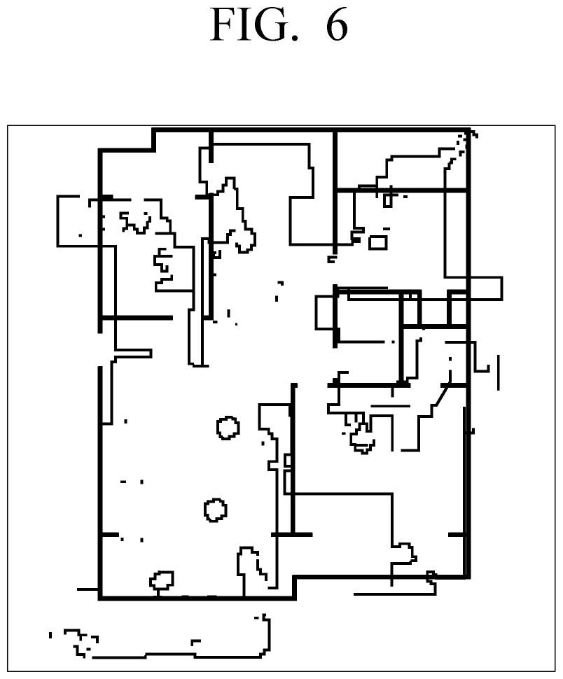

Step a3: Perform matching-fusion on the mobile phone to generate a result plan, as shown in FIG. 6.

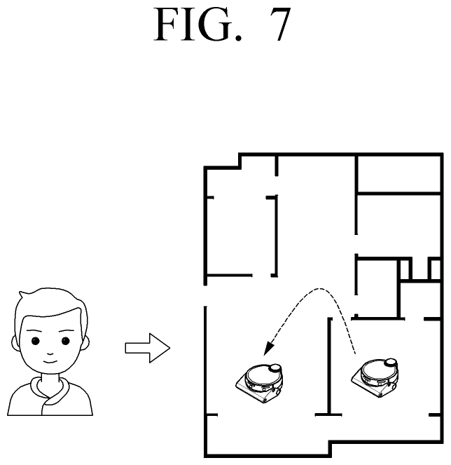

Step a4: A user may specify a room region to be scanned by the sweeper, as shown in FIG. 7.

Scenario II: The IoT device is automatically controlled by the service APP on the mobile phone, for example, using the following steps b1 to b3 to control a smart TV to be turned on.

Step b1: Obtain, based on a method embodiment of the present application, an accurate house-type display plan of a target house, and add, based on a 3D map corresponding to the house-type display plan, the IoT device (such as a smart TV, a refrigerator, a curtain, and a lamp) to a corresponding room.

Step b2: Take the smart TV as a central device, the 3D map being deployed therein.

Step b3: A user inputs a voice instruction through the smart TV to indicate to open a TV in a living room, and a IoT service locates an intelligent device indicated by the voice instruction based on semantic information about the 3D map, to learn that a target device needed to be opened currently is the TV in the living room, and control to open the TV.

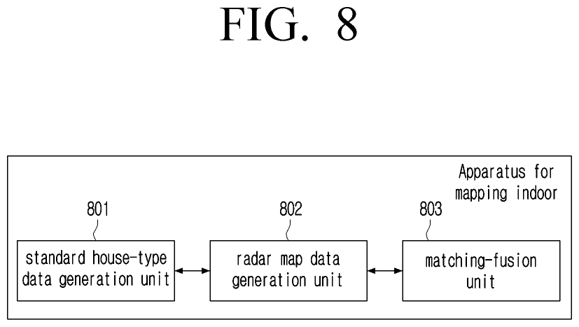

Based on the above method of indoor mapping, the disclosed embodiments provide an indoor mapping apparatus, as shown in FIG. 8, including:
a standard house-type data generation unit 801, configured to generate, based on a standard house-type plan of a target house, vectorized house-type structure data for the target house using a deep neural network;
a radar map data generation unit 802, configured to acquire a first radar map by scanning a travelable space of a first region with a radar, the first region containing at least one room of the target house; and
a matching-fusion unit 803, configured to perform image matching-fusion processing based on the first radar map and the house-type structure data to obtain a house-type display plan of the target house.

The above method and apparatus are based on the same inventive concept. Since the principles of the method and apparatus for solving the problems are similar, the implementation of the apparatus and method may be referred to each other, and the repetition will not be repeated.

Based on the above method, the disclosed embodiments further provide an indoor mapping device, including a processor and a memory. The memory has stored therein an APP executable by the processor for causing the processor to execute the above method for mapping indoor. Specifically, a system or apparatus equipped with a storage medium may be provided, the storage medium storing thereon a software program code realizing the functions of any one of implementations of the above embodiments, and causing a computer (or central processing unit (CPU) or microprocessor unit (MPU)) of the system or apparatus to read out and execute the program code stored in the storage medium. Furthermore, part or all the actual operations may be performed by an operating system operated on the computer through instructions based on the program code. It is possible to write the program code read from the storage medium into a memory provided in an expansion board inserted into a computer or into a memory provided in an expansion unit connected to the computer, and then cause a CPU installed on the expansion board or the expansion unit to perform part or all the actual operations based on instructions of the program code, thereby realizing the functions of any one of implementations of the above method for mapping indoor.

The memory may be specifically implemented as various storage media such as an electrically erasable programmable read-only memory (EEPROM), a flash memory, and a programmable read-only memory (PROM). The processor may be implemented to include one or more central processors or one or more field programmable gate arrays (FPGAs), the FPGAs integrating one or more central processor cores. In particular, the central processors or central processor cores may be implemented as a CPU or a microcontroller unit (MCU).

The embodiments of the present application further implement a computer program product including computer programs or instructions, the computer programs or instructions, when executed by a processor, implementing the steps of the above method for mapping indoor.

Not all the steps and modules in the above flowcharts and structure diagrams are necessary, and some steps or modules may be omitted according to actual needs. The performing order of the steps is not fixed and may be adjusted as desired. The division of various modules is merely to facilitate the description of the functional division adopted. In actual implementation, a module may be realized by a plurality of modules; the functions of a plurality of modules may also be realized by the same module; and these modules may be located at the same device or in different devices.

The hardware modules in the various implementations may be implemented mechanically or electronically. For example, a hardware module may include a specially designed permanent circuit or logic device (for example, a dedicated processor such as an FPGA or application specific integrated circuit (ASIC)) for performing specific operations. The hardware module may further include a programmable logic device or circuit (for example, including a general-purpose processor or other programmable processors) temporarily configured by software for performing specific operations. The implementation of the hardware modules, whether by mechanical means, dedicated permanent circuits, or temporarily configured circuits (for example, configured by software), may be determined by cost and time considerations.

In the specification, “schematic” means “serving as an example, instance, or illustration”, and any illustration and implementation described herein as “schematic” are not to be construed as a more preferred or advantageous technical solution. In the interest of clarity, only the relevant parts are shown schematically in each drawing and do not represent the actual structure of the product. In addition, in order to make the drawing simple and easy to understand, for the components with the same structure or function in some drawings, only one of them is schematically illustrated, or only one of them is indicated. In the specification, “one” does not mean to limit the number of relevant portions to “only one”, and “one” does not mean to exclude the case that the number of relevant portions is “more than one”. In the specification, terms such as “upper”, “lower”, “front”, “back”, “left”, “right”, “inner”, “outer”, are used merely to represent relative positional relationships between the relevant portions, and do not limit the absolute positions of these relevant portions.

The solutions described in the specification and embodiments, if involving personal information processing, will be processed on the premise of legality (for example, obtaining the consent of the personal information subject or being necessary for the performance of the contract), and will only be processed within the specified or agreed scope. The user refuses to process personal information other than the necessary information required for basic functions without affecting the user in using basic functions.

In summary, the above are only some embodiments and are not intended to limit the scope of protection. Any modification, equivalent replacement, improvement made within the spirit and principle of the disclosed embodiments shall be included in the scope of protection of the present invention.

What is claimed is:

1. A method for mapping indoor, comprising:
generating, based on a standard house plan of a target house, vectorized house structure data for the target house using a deep neural network;
acquiring a first radar map by scanning a travelable space of a first region with a radar, the first region containing at least one room of the target house; and
performing image matching-fusion processing based on the first radar map and the house structure data to obtain a house display plan of the target house.

2. The method according to claim 1, wherein the acquiring the first radar map by scanning the travelable space of the first region with the radar comprises:
scanning the travelable space of the first region by using the radar to obtain an original radar map; and
filtering a noise region in the original radar map to obtain the first radar map.

3. The method according to claim 1, wherein the performing the image matching-fusion processing comprises:
constructing a plurality of standard house sub-plans of the target house based on the house structure data, the plurality of standard house sub-plans containing at least one room of the target house;
selecting a first standard house sub-plan that best matches with the first radar map from the plurality of standard house sub-plans;
determining a matching adjustment angle of the first radar map corresponding to the first standard sub-plan, the matching adjustment angle being an angle at which the first radar map needs to rotate and/or flip in order to be consistent with a direction of the first standard house sub-plan;
determining, for each first room in the first radar map, a room corresponding to the first room in the first standard house sub-plan;
performing optimization iterative fitting on a center position, length, and width of the first room by taking a size of the room corresponding to the first room as a target to obtain a size-matching parameter of the first room, the size-matching parameter including a center position, length, and width of the first room, and room identification information; and
performing adjustment on the first radar map based on the matching adjustment angle and the size-matching parameter of the first room to obtain the house display plan of the target house.

4. The method according to claim 3, wherein the selecting the first standard house sub-plan that best matches with the first radar map from the plurality of standard house sub-plans, and the determining the matching adjustment angle of the first radar map corresponding to the first standard sub-plan includes:
performing room segmentation on the first radar map, a segmented room of the first radar map with a maximum area being a main region;
determining first similarities between the main region and each of the plurality of standard house sub-plans by (i) taking the matching adjustment angle as a similarity parameter, (ii) selecting a first similarity greater than a preset coarse similarity threshold, and (iii) taking a matching adjustment angle corresponding to the first similarity selected as a candidate matching adjustment angle corresponding to the first standard house sub-plan;
adjusting the first radar map based on each candidate matching adjustment angle;
calculating second similarities between an adjusted first radar map and the corresponding standard house sub-plan, the second similarities being obtained using a weighted calculation method based on a preset fine similarity parameter, the fine similarity parameter including an intersection ratio, a coverage rate, and/or an length-width ratio;
taking a standard house sub-plan of the plurality of standard house sub-plans corresponding to a maximum value of the second similarities as the first standard house sub-plan that best matches with the first radar map; and
taking a corresponding candidate matching adjustment angle as the corresponding matching adjustment angle of the first radar map.

5. The method according to claim 3, wherein the determining, for each first room in the first radar map, the corresponding room of the first room in the first standard house sub-plan comprises:
calculating a similarity between the first room and each room in the first standard house sub-plan with an intersection ratio as a similarity parameter; and
taking a room corresponding to a maximum similarity as the corresponding room of the first room in the first standard house sub-plan.

6. The method according to claim 3, wherein the performing the image matching-fusion processing further comprises, for each first room:
determining, in a case that there is a second room, a size ratio between a standard house size of the first room and the size-matching parameter of the first room, the second room being a room of the target house excluded from the first radar map, the standard house size being size data of the corresponding room of the first room in the first standard house sub-plan;
adjusting corresponding vectorized house structure data of each second room according to an average value of the size ratio to obtain a size-matching parameter of the second room; and
adding a corresponding room to the house display plan based on the size-matching parameter of the second room.

7. The method according to claim 1, wherein rooms within the standard house sub-plan have connectivity.

8. A device for mapping indoor, comprising
a memory; and
at least one processor configured to:
generate, based on a standard house plan of a target house, vectorized house structure data for the target house using a deep neural network;
acquire a first radar map by scanning a travelable space of a first region with a radar, the first region containing at least one room of the target house; and
perform image matching-fusion processing based on the first radar map and the house structure data to obtain a house display plan of the target house.

9. The device as claimed in claim 8, wherein the at least one processor being configured to acquire the first radar map by scanning the travelable space of the first region with the radar includes being configured to:
scan the travelable space of the first region by using the radar to obtain an original radar map; and
filter a noise region in the original radar map to obtain the first radar map.

10. The device as claimed in claim 8, wherein the at least one processor being configured to perform image matching-fusion processing includes being configured to:
construct a plurality of standard house sub-plans of the target house based on the house structure data, the plurality of standard house sub-plans containing at least one room of the target house;
select a first standard house sub-plan that best matches with the first radar map from the plurality of standard house-type sub-plans;
determine a matching adjustment angle of the first radar map corresponding to the first standard sub-plan, the matching adjustment angle being an angle at which the first radar map needs to rotate and/or flip in order to be consistent with a direction of the first standard house sub-plan;
determine, for each first room in the first radar map, a room corresponding to the first room in the first standard house sub-plan;
perform optimization iterative fitting on a center position, length, and width of the first room by taking a size of the room corresponding to the first room as a target to obtain a size-matching parameter of the first room, the size-matching parameter including a center position, length, and width of the first room, and room identification information; and
perform adjustment on the first radar map based on the matching adjustment angle and the size-matching parameter of the first room to obtain the house display plan of the target house.

11. The device as claimed in claim 10, wherein the at least one processor being configured to select the first standard house sub-plan that best matches with the first radar map from the plurality of standard house-type sub-plans, and to determine the matching adjustment angle of the first radar map corresponding to the first standard sub-plan includes being configured to:
perform room segmentation on the first radar map, a segmented room of the first radar map with a maximum area being a main region;
determine first similarities between the main region and each of the plurality of standard house sub-plans by (i) taking the matching adjustment angle as a similarity parameter, (ii) selecting a first similarity greater than a preset coarse similarity threshold, and (iii) taking a matching adjustment angle corresponding to the first similarity selected as a candidate matching adjustment angle corresponding to the first standard house sub-plan;
adjust the first radar map based on each candidate matching adjustment angle;
calculate second similarities between an adjusted first radar maps and the corresponding standard house sub-plan, the second similarities being obtained using a weighted calculation method based on a preset fine similarity parameter, the fine similarity parameter including an intersection ratio, a coverage rate, and/or an length-width ratio;
take a standard house sub-plan of the plurality of standard house sub-plans corresponding to a maximum value of the second similarities as the first standard house-type sub-plan that best matches with the first radar map; and
take a corresponding candidate matching adjustment angle as the corresponding matching adjustment angle of the first radar map.

12. The device as claimed in claim 10, wherein the at least one processor being configured to determine, for each first room in the first radar map, the corresponding room of the first room in the first standard house sub-plan includes being configured to:
calculate a similarity between the first room and each room in the first standard house sub-plan with an intersection ratio as a similarity parameter; and
take a room corresponding to a maximum similarity as the corresponding room of the first room in the first standard house sub-plan.

13. The device as claimed in claim 10, wherein the at least one processor being configured to perform image matching-fusion processing further includes being configured to, for each first room:
determine, in a case that there is a second room, a size ratio between a standard house size of the first room and the size-matching parameter of the first room the second room being a room of the target house excluded from the first radar map, the standard house size being size data of the corresponding room of the first room in the first standard house sub-plan;
adjust corresponding vectorized house structure data of each second room according to an average value of the size ratio to obtain a size-matching parameter of the second room; and
add a corresponding room to the house display plan based on the size-matching parameter of the second room.

14. The device as claimed in claim 8, wherein rooms within the standard house sub-plan have connectivity.

15. A computer-readable storage medium storing therein computer-readable instructions, the computer-readable instructions being used for executing a method, the method comprising:
generating, based on a standard house-type plan of a target house, vectorized house-type structure data for the target house using a deep neural network;
acquiring a first radar map by scanning a travelable space of a first region with a radar, the first region containing at least one room of the target house; and
performing image matching-fusion processing based on the first radar map and the house-type structure data to obtain a house-type display plan of the target house.

16. The computer readable storage medium according to claim 15, wherein the acquiring the first radar map by scanning the travelable space of the first region with the radar includes:
scanning the travelable space of the first region by using the radar to obtain an original radar map; and
filtering a noise region in the original radar map to obtain the first radar map.

17. The computer readable storage medium according to claim 15, wherein the performing the image matching-fusion processing includes:
constructing a plurality of standard house sub-plans of the target house based on the house structure data, the plurality of standard house sub-plans containing at least one room of the target house;
selecting a first standard house sub-plan that best matches with the first radar map from the plurality of standard house sub-plans;
determining a matching adjustment angle of the first radar map corresponding to the first standard sub-plan, the matching adjustment angle being an angle at which the first radar map needs to rotate and/or flip in order to be consistent with a direction of the first standard house sub-plan;
determining, for each first room in the first radar map, a room corresponding to the first room in the first standard house sub-plan;
performing optimization iterative fitting on a center position, length, and width of the first room by taking a size of the room corresponding to the first room as a target to obtain a size-matching parameter of the first room, the size-matching parameter including a center position, length, and width of the first room, and room identification information; and
performing adjustment on the first radar map based on the matching adjustment angle and the size-matching parameter of the first room to obtain the house display plan of the target house.

18. The computer readable storage medium according to claim 17, wherein the selecting the first standard house sub-plan that best matches with the first radar map from the plurality of standard house sub-plans, and the determining the matching adjustment angle of the first radar map corresponding to the first standard sub-plan includes:
performing room segmentation on the first radar map, a segmented room of the first radar map with a maximum area being a main region;
determining first similarities between the main region and each of the plurality of standard house sub-plans by (i) taking the matching adjustment angle as a similarity parameter, (ii) selecting a first similarity greater than a preset coarse similarity threshold, and (iii) taking a matching adjustment angle corresponding to the first similarity selected as a candidate matching adjustment angle corresponding to the first standard house sub-plan;
adjusting the first radar map based on each candidate matching adjustment angle;
calculating second similarities between an adjusted first radar map and the corresponding standard house sub-plan, the second similarities being obtained using a weighted calculation method based on a preset fine similarity parameter, the fine similarity parameter including an intersection ratio, a coverage rate, and/or an length-width ratio;
taking a standard house sub-plan of the plurality of standard house sub-plans corresponding to a maximum value of the second similarities as the first standard house sub-plan that best matches with the first radar map; and
taking a corresponding candidate matching adjustment angle as the corresponding matching adjustment angle of the first radar map.

19. The computer readable storage medium according to claim 17, wherein the determining, for each first room in the first radar map, the corresponding room of the first room in the first standard house sub-plan includes:
calculating a similarity between the first room and each room in the first standard house sub-plan with an intersection ratio as a similarity parameter; and
taking a room corresponding to a maximum similarity as the corresponding room of the first room in the first standard house sub-plan.

20. The computer readable storage medium according to claim 17, wherein the performing the image matching-fusion processing further includes, for each first room:
determining, in a case that there is a second room, a size ratio between a standard house size of the first room and the size-matching parameter of the first room, the second room being a room of the target house excluded from the first radar map, the standard house size being size data of the corresponding room of the first room in the first standard house sub-plan;
adjusting corresponding vectorized house structure data of each second room according to an average value of the size ratio to obtain a size-matching parameter of the second room; and
adding a corresponding room to the house display plan based on the size-matching parameter of the second room.
